(19) United States
(12) Patent Application Publication
(10) Pub. No.: US 2025/0300415 A1
(43) Pub. Date: Sep. 25, 2025

(54) Detection Device and Connector Assembly System

(71) Applicants: TE Connectivity Solutions GmbH, Schaffhausen (CH); Tyco Electronics (Shanghai) Co., Ltd., Shanghai (CN)

(72) Inventors: An (Joshua) Yang, Shanghai (CN); Lvhai (Samuel) Hu, Shanghai (CN); Roberto Francisco-Yi Lu, Bellevue, WA (US)

(73) Assignees: TE Connectivity Solutions GmbH, Schaffhausen (CH); Tyco Electronics (Shanghai) Co., Ltd., Shanghai (CN)

(21) Appl. No.: 19/089,314

(22) Filed: Mar. 25, 2025

(30) Foreign Application Priority Data
Mar. 25, 2024 (CN) 202410348787.4

(51) Int. Cl. H01R 43/20; G01R 31/68

(52) U.S. Cl. CPC H01R 43/20; G01R 31/68

(57) ABSTRACT

A detection device for detecting an insertion depth of a connector terminal in a connector housing includes a detection component and a detection circuit. The detection component is inserted into a front port of the connector housing and electrically contacts a front end of the connector terminal inserted in the connector housing from a rear port of the connector housing. The detection circuit has one end electrically connected to the detection component and the other end electrically connected to a rear end of the connector terminal or to a connector cable connected to the rear end of the connector terminal. The detection circuit is in a connected state when the connector terminal reaches a predetermined insertion depth and electrically contacts the detection component. The detection circuit is in a disconnected state when the connector terminal does not reach the predetermined insertion depth and does not electrically contact the detection component.

### CROSS-REFERENCE TO RELATED APPLICATION

This application claims the benefit of the filing date under 35 U.S.C. § 119 (a)-(d) of Chinese Patent Application No. CN202410348787.4, filed on Mar. 25, 2024.

### FIELD OF THE INVENTION

The present invention relates to a detection device and connector assembly system and, more particularly, to a detection device for detecting the insertion depth of a connector terminal in a connector housing, and a connector assembly system comprising the detection device.

### BACKGROUND OF THE INVENTION

During the assembly process of a connector, a connector terminal is initially manually inserted into a socket of a connector housing, to the predetermined depth using a simple tool. Due to the interference fit between the connector terminal and the socket of the connector housing, proper insertion of the connector terminal requires a certain amount of insertion force. However, manual insertion of connector terminal lacks precise stroke control, making it difficult to accurately control the insertion depth of the connector terminal, resulting in improper insertion issues that affect the quality of the connector.

### SUMMARY OF THE INVENTION

A detection device for detecting an insertion depth of a connector terminal in a connector housing includes a detection component and a detection circuit. The detection component is inserted into a front port of the connector housing. The detection component electrically contacts a front end of the connector terminal inserted in the connector housing from a rear port of the connector housing. The detection circuit has one end electrically connected to the detection component and the other end electrically connected to a rear end of the connector terminal or to a connector cable connected to the rear end of the connector terminal. The detection circuit is in a connected state when the connector terminal reaches a predetermined insertion depth and electrically contacts the detection component. The detection circuit is in a disconnected state when the connector terminal does not reach the predetermined insertion depth and does not electrically contact the detection component.

### BRIEF DESCRIPTION OF DRAWINGS

The invention will now be described by way of example with reference to the accompanying figures, of which:

FIG. 1 is a perspective view of a detection component of a detection device and a connector according to an exemplary embodiment;

FIG. 2 is a schematic sectional view of a detection device according to an exemplary embodiment and the connector of FIG. 1;

FIG. 3 is a perspective view of a detection component of a detection device and a connector according to another exemplary embodiment; and

FIG. 4 is a schematic sectional view of a detection device according to another exemplary embodiment and the connector of FIG. 3.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

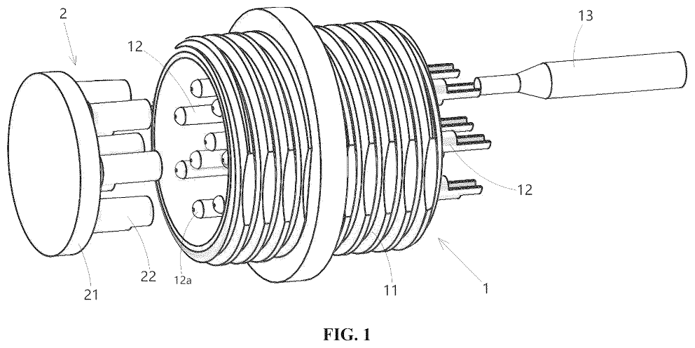

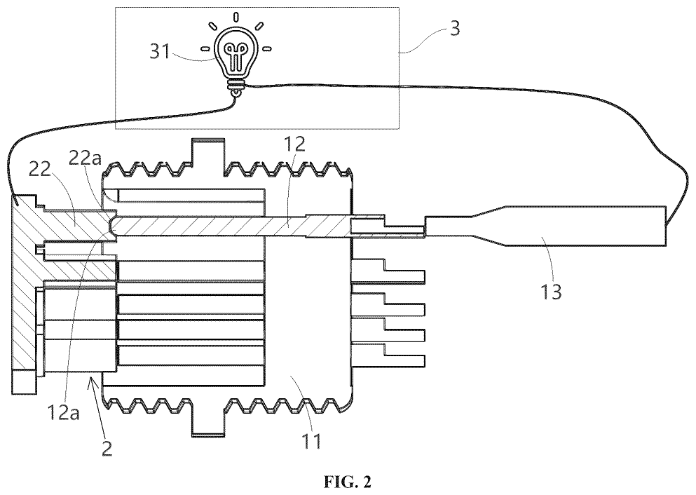

An exemplary embodiment of a detection device is now described with reference to FIGS. 1-2. The detection device detects an insertion depth of a connector terminal 12 inserted into a connector housing 11 of a connector 1.

The detection device, as shown in FIGS. 1-2, comprises a detection component 2 and a detection circuit 3. The detection component 2 is inserted into the front port of the connector housing 11 for electrical contact with the front end of the connector terminal 12 inserted from the rear port of the connector housing 11. As shown in FIG. 2, one end of a detection circuit 3 is electrically connected to the detection component 2, and the other end of the detection circuit 3 is electrically connected to the rear end of the connector terminal 12 or to a connector cable 13 connected to the rear end of the connector terminal 12.

When the insertion depth of the connector terminal 12 reaches the predetermined insertion depth, the connector terminal 12 makes electrical contact with the detection component 2, so that the detection circuit 3 is in a connected state. When the insertion depth of connector terminal 12 does not reach the predetermined insertion depth, the connector terminal 12 does not come into contact with the detection component 2, so that the detection circuit 3 is in a disconnected state.

As shown in FIG. 1, the connector terminal 12 is a male connector terminal. The detection component 2, as shown in FIG. 1, includes a base 21 and a post portion 22 connected to the base 21. As shown in FIG. 2, a recessed portion 22a is formed on the rear end of the post portion 22, which is suitable for mating with a protruding front end portion 12a of the male connector terminal 12. When the insertion depth of the male connector terminal 12 reaches the predetermined insertion depth, the protruding front end portion 12a of the male connector terminal 12 is inserted into the recessed portion 22a at the rear end of the post portion 22 of the detection component 2 to make electrical contact with the detection component 2.

The detection device also includes a judgment device. The judgment device determines whether the insertion depth of the connector terminal 12 has reached the predetermined insertion depth based on the electrical connection state of detection circuit 3. When the detection circuit 3 is in the connected state, the judgment device determines that the insertion depth of the connector terminal 12 has reached the predetermined insertion depth. When the detection circuit 3 is in the disconnected state, the judgment device determines that the insertion depth of the connector terminal 12 has not reached the predetermined insertion depth.

As shown in FIG. 2, the detection circuit 3 includes an indicator light 31 connected in series in the detection circuit 3, allowing an operator to determine whether the insertion depth of the connector terminal 12 has reached the predetermined insertion depth based on the status of the indicator light 31. When the indicator light 31 is on, the operator determines that the insertion depth of connector terminal 12 has reached the predetermined insertion depth. When the indicator light 31 is off, the operator determines that the insertion depth of the connector terminal 12 has not reached the predetermined insertion depth.

In an alternative embodiment, the detection circuit 3 includes an elastic clip connected to its other end. The elastic clip is suitable for clamping onto the rear end of the connector terminal 12 to electrically connect the other end of the detection circuit 3 to the connector terminal 12. In another alternative embodiment, the detection circuit 3 includes a contact probe connected to its other end, which is used to make electrical contact with the rear end of the connector terminal 12 to electrically connect the other end of the detection circuit 3 to the connector terminal 12.

The connector 1, according to an exemplary embodiment, is now described with reference to FIGS. 1-2. The exemplary embodiment of the connector 1 includes multiple male connector terminals 12, as shown in FIG. 1. The multiple male connector terminals 12 are inserted one by one into the connector housing 11 of the connector 1. An exemplary embodiment of a detection component 2 corresponding to this embodiment of the connector 1 includes multiple post portions 22 connected to the base 21, which correspond to the multiple male connector terminals 12. The multiple post portions 22 are used for respectively electrically contacting the multiple male connector terminals 12. A detection device corresponding to this embodiment of the connector 1 includes multiple detection circuits 3. One end of each detection circuit 3 is electrically connected to the base 21 of the detection component 2, and the other end of each detection circuit 3 is electrically connected to one male connector terminal 12 of the multiple male connector terminals 12.

Another exemplary embodiment of a connector 1 is now described. In this exemplary embodiment of the connector 1, the connector 1 includes multiple male connector terminals 12, and the multiple male connector terminals 12 are inserted together into the connector housing 11 of the connector 1. An exemplary embodiment of the detection component 2 corresponding to this embodiment of the connector 1 includes multiple post portions 22 connected to the base 21, which correspond to multiple male connector terminals 12 and are used for electrical contact with the multiple male connector terminals 12, respectively. A detection device corresponding to this embodiment of the connector 1 includes a single detection circuit 3, one end of which is electrically connected to the base 21 of the detection component 2, and the other end of which is electrically connected to one of the multiple male connector terminals 12.

An exemplary embodiment of a connector assembly system is now described. The connector assembly system includes a first fixture, a second fixture, a moving device, and a detection device according to one of the aforementioned embodiments. The first fixture is used to clamp the connector housing 11. The second fixture is used to clamp the connector terminal 12 or to clamp the connector cable 13 connected to the connector terminal 12. The moving device is used to move the second fixture to insert the connector terminal 12 into the connector housing 11. The detection device is used to detect the insertion depth of connector terminal 12. The detection component 2 of the detection device is inserted into the front port of the connector housing 11. One end of the detection circuit 3 of the detection device is electrically connected to the detection component 2, and the other end is electrically connected to the connector terminal 12 or the connector cable 13. When the detection circuit 3 is in a connected state, the detection device determines that the insertion depth of the connector terminal 12 has reached the predetermined insertion depth and controls the moving device to stop inserting the connector terminal 12 forward.

In an exemplary embodiment, the second fixture is adapted to simultaneously clamp multiple connector terminals 12, and the moving device is adapted to simultaneously insert multiple connector terminals 12 clamped by the second fixture into the connector housing 11 by moving the second fixture. The detection device corresponding to this embodiment includes a single detection circuit 3, one end of which is electrically connected to the detection component 2, and the other end is electrically connected to one of the multiple connector terminals 12.

In another exemplary embodiment, the second fixture is adapted to clamp a single connector terminal 12, and the moving device is adapted to insert multiple connector terminals 12 one by one into the connector housing 11 by moving the second fixture. The detection device corresponding to this embodiment includes multiple detection circuits 3, one end of each detection circuit 3 is electrically connected to the detection component 2, and the other end of each detection circuit 3 is electrically connected to one connector terminal 12 of the multiple connector terminals 12.

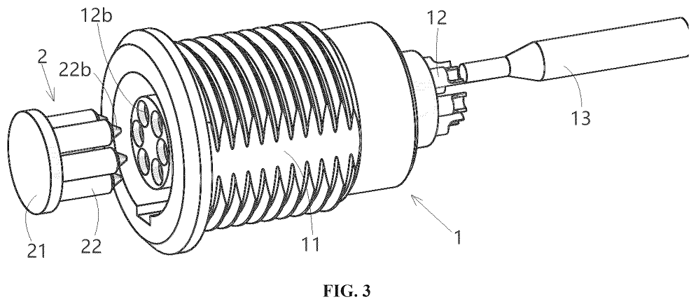

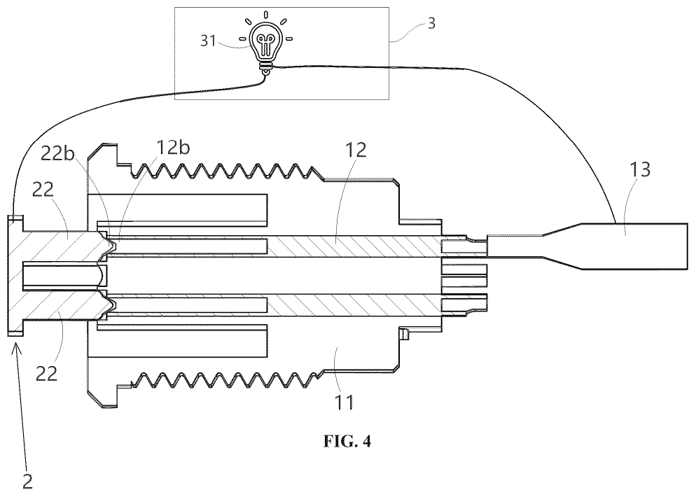

Another exemplary embodiment of the detection device is now described with references to FIGS. 3-4. The detection device detects the insertion depth of a connector terminal 12 inserted into a connector housing 11 of a connector 1.

As shown in FIG. 4, the detection device comprises a detection component 2 and a detection circuit 3. The detection component 2 is inserted into the front port of the connector housing 11 for electrical contact with the front end of the connector terminal 12 inserted from the rear port of the connector housing 11. One end of detection circuit 3 is electrically connected to the detection component 2, and the other end of the detection circuit 3 is electrically connected to the rear end of connector terminal 12 or to a connector cable 13 connected to the rear end of connector terminal 12.

When the insertion depth of the connector terminal 12 reaches the predetermined insertion depth, the connector terminal 12 makes electrical contact with the detection component 2, so that the detection circuit 3 is in a connected state. When the insertion depth of connector terminal 12 does not reach the predetermined insertion depth, the connector terminal 12 does not come into contact with detection component 2, so that the detection circuit 3 is in a disconnected state.

As shown in FIG. 3, the connector terminal 12 is a female connector terminal, and the detection component 2 includes a base 21 and a post portion 22 connected to the base 21. A protruding portion 22b is formed on the rear end of the post portion 22, which is suitable for mating with an insertion cavity 12b at the front end of the female connector terminal 12. When the insertion depth of the female connector terminal 12 reaches the predetermined insertion depth, the protruding portion 22b at the rear end of the post portion 22 of the detection component 2 is inserted into the insertion cavity 12b at the front end of the female connector terminal 12 to make electrical contact with it.

The detection device also includes a judgment device. The judgment device determines whether the insertion depth of the connector terminal 12 has reached the predetermined insertion depth based on the electrical connection state of detection circuit 3. When the detection circuit 3 is in the connected state, the judgment device determines that the insertion depth of the connector terminal 12 has reached the predetermined insertion depth. When the detection circuit 3 is in the disconnected state, the judgment device determines that the insertion depth of the connector terminal 12 has not reached the predetermined insertion depth.

As shown in FIG. 4, the detection circuit 3 includes an indicator light 31 connected in series in the detection circuit 3, allowing an operator to determine whether the insertion depth of the connector terminal 12 has reached the predetermined insertion depth based on the status of the indicator light 31. When the indicator light 31 is on, the operator determines that the insertion depth of connector terminal 12 has reached the predetermined insertion depth. When the indicator light 31 is off, the operator determines that the insertion depth of connector terminal 12 has not reached the predetermined insertion depth.

In an alternative embodiment, the detection circuit 3 includes an elastic clip connected to its other end, which is suitable for clamping onto the rear end of the connector terminal 12 to electrically connect the other end of the detection circuit 3 to the connector terminal 12. In another alternative embodiment, the detection circuit 3 includes a contact probe connected to its other end, which is used to make electrical contact with the rear end of the connector terminal 12 to electrically connect the other end of the detection circuit 3 to the connector terminal 12.

The connector 1, according to an exemplary embodiment, is now described with reference to FIGS. 3-4. The connector 1 comprises multiple female connector terminals 12, as shown in FIG. 3. The multiple female connector terminals 12 are individually inserted into the connector housing 11 of the connector 1. An exemplary embodiment of the detection component 2 corresponding to this embodiment of the connector 1 includes multiple post portions 22 connected to the base 21, which correspond to multiple female connector terminals 12 for respectively electrically contacting the female connector terminals 12. A detection device corresponding to this embodiment of the connector 1 includes multiple detection circuits 3. One end of each detection circuit 3 is electrically connected to the base 21 of the detection component 2, and the other end of each detection circuit 3 is electrically connected to one female connector terminal 12 of the multiple female connector terminals 12.

Another exemplary embodiment of the connector 1 is now described. In this exemplary embodiment of the connector 1, the connector 1 includes multiple female connector terminals 12, and the multiple female connector terminals 12 are inserted together into the connector housing 11 of the connector 1. An exemplary embodiment of a detection component 2 corresponding to this embodiment of the connector 1 includes multiple post portions 22 connected to the base 21, which correspond to multiple female connector terminals 12. The multiple post portions 22 are used for respectively electrically contacting the multiple female connector terminals 12. A detection device corresponding to this embodiment of the connector 1 includes a single detection circuit 3, one end of which is electrically connected to the base 21 of the detection component 2, and the other end of which is electrically connected to one of the multiple female connector terminals 12.

An exemplary embodiment of a connector assembly system is now described. The connector assembly system includes a first fixture, a second fixture, a moving device, and a detection device according to one of the aforementioned embodiments. The first fixture is used to clamp the connector housing 11. The second fixture is used to clamp the connector terminal 12 or to clamp the connector cable 13 connected to the connector terminal 12. The moving device is used to move the second fixture to insert the connector terminal 12 into the connector housing 11. The detection device is used to detect the insertion depth of connector terminal 12. The detection component 2 of the detection device is inserted into the front port of the connector housing 11, and one end of the detection circuit 3 of the detection device is electrically connected to the detection component 2, and the other end is electrically connected to the connector terminal 12 or the connector cable 13. When the detection circuit 3 is in a connected state, the detection device determines that the insertion depth of the connector terminal 12 has reached the predetermined insertion depth and controls the moving device to stop inserting the connector terminal 12 forward.

In an exemplary embodiment, the second fixture is adapted to simultaneously clamp multiple connector terminals 12, and the moving device is adapted to simultaneously insert multiple connector terminals 12 clamped by the second fixture into the connector housing 11 by moving the second fixture. The detection device corresponding to this embodiment includes a single detection circuit 3, one end of which is electrically connected to the detection component 2, and the other end is electrically connected to one of the multiple connector terminals 12.

In another exemplary embodiment, the second fixture is adapted to clamp a single connector terminal 12, and the moving device is adapted to insert multiple connector terminals 12 one by one into the connector housing 11 by moving the second fixture. The detection device corresponding to this embodiment includes multiple detection circuits 3, one end of each detection circuit 3 is electrically connected to the detection component 2, and the other end of each detection circuit 3 is electrically connected to one connector terminal 12 of the multiple connector terminals 12.

In the aforementioned exemplary embodiments according to the present invention, the detection device can accurately detect the insertion depth of the connector terminal 12, thereby enabling precise control of the insertion depth of the connector terminal 12 and greatly improving the quality of the connector 1.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

1. A detection device for detecting an insertion depth of a connector terminal in a connector housing, comprising:
a detection component inserted into a front port of the connector housing, the detection component electrically contacts a front end of the connector terminal inserted into the connector housing from a rear port of the connector housing; and
a detection circuit having a first end electrically connected to the detection component and a second end electrically connected to a rear end of the connector terminal or to a connector cable connected to the rear end of the connector terminal, the detection circuit is in a connected state when the connector terminal reaches a predetermined insertion depth in the connector housing and electrically contacts the detection component, the detection circuit is in a disconnected state when the connector terminal does not reach the predetermined insertion depth and does not electrically contact the detection component.

2. The detection device of claim 1, wherein the detection component has a base, a post portion connected to the base, and a recessed portion formed on a rear end of the post portion, the recessed portion mates with a protruding front end portion of a male connector terminal, when the insertion depth of the male connector terminal reaches the predetermined insertion depth, the protruding front end portion is inserted into the recessed portion and electrically contacts the detection component.

3. The detection device of claim 2, wherein the post portion is one of a plurality of post portions connected to the base, each post portion corresponds to one male connector terminal of a plurality of male connector terminals.

4. The detection device of claim 3, wherein the detection circuit is one of a plurality of detection circuits, the first end of each detection circuit is electrically connected to the base of the detection component, and the second end of each detection circuit is electrically connected to one of the male connector terminals.

5. The detection device of claim 3, wherein the detection device has a single detection circuit, the first end of the detection circuit is electrically connected to the base of the detection component, and the second end of the detection circuit is electrically connected to one of the male connector terminals.

6. The detection device of claim 1, wherein the detection component has a base, a post portion connected to the base, and a protruding portion formed on a rear end of the post portion, the protruding portion mates with an insertion cavity formed in the front end of a female connector terminal, when the insertion depth of the female connector terminal reaches the predetermined insertion depth, the protruding portion is inserted into the insertion cavity and electrically contacts the female connector terminal.

7. The detection device of claim 6, wherein the post portion is one of a plurality of post portions connected to the base, each post portion corresponds to one female connector terminal of a plurality of female connector terminals.

8. The detection device of claim 7, wherein the detection device has a plurality of detection circuits, the first end of each detection circuit is electrically connected to the base of the detection component, and the second end of each detection circuit is electrically connected to one of the female connector terminals.

9. The detection device of claim 7, wherein the detection device has a single detection circuit, the first end of the detection circuit is electrically connected to the base of the detection component, and the second end of the detection circuit is electrically connected to one of the female connector terminals.

10. The detection device of claim 1, further comprising a judgment device judging whether the insertion depth of the connector terminal has reached the predetermined insertion depth based on an electrical connection state of the detection circuit, when the detection circuit is in the connected state, the judgment device determines that the insertion depth of the connector terminal has reached the predetermined insertion depth, when the detection circuit is in the disconnected state, the judgment device determines that the insertion depth of the connector terminal has not reached the predetermined insertion depth.

11. The detection device according of claim 1, wherein the detection circuit has an indicator light, the indicator light is on when the connector terminal has reached the predetermined insertion depth, and the indicator light is off when the connector terminal has not reached the predetermined insertion depth.

12. The detection device of claim 1, wherein the first end of the detection circuit is electrically connected to the base of the detection component and the second end has an elastic clip, the elastic clip clamps onto the rear end of the connector terminal to electrically connect the detection circuit to the connector terminal.

13. The detection device of claim 1, wherein the first end of the detection circuit is electrically connected to a base of the detection component and the second end has a contact probe, the contact probe electrically contacts the rear end of the connector terminal to electrically connect the detection circuit to the connector terminal.

14. A connector assembly system, comprising:
a first fixture clamping a connector housing;
a second fixture clamping a connector terminal or a connector cable connected to the connector terminal;
a moving device moving the second fixture to insert the connector terminal into the connector housing; and
a detection device detecting an insertion depth of the connector terminal in the connector housing, the detection device includes a detection component inserted into a front port of the connector housing, the detection component electrically contacts a front end of the connector terminal inserted in the connector housing from a rear port of the connector housing, and a detection circuit having a first end electrically connected to the detection component and a second end electrically connected to a rear end of the connector terminal or to the connector cable connected to the rear end of the connector terminal, the detection circuit is in a connected state when the connector terminal reaches a predetermined insertion depth and electrically contacts the detection component, when the detection circuit is in the connected state, the detection device determines that the insertion depth of the connector terminal has reached the predetermined insertion depth and controls the moving device to stop inserting the connector terminal into the connector housing.

15. The connector assembly system of claim 14, wherein the connector terminal is one of a plurality of connector terminals, the second fixture simultaneously clamps the plurality of connector terminals, and the moving device simultaneously inserts the plurality of connector terminals clamped by the second fixture into the connector housing by moving the second fixture.

16. The connector assembly system of claim 15, wherein the detection device has a single detection circuit.

17. The connector assembly system of claim 14, wherein the second fixture clamps a single connector terminal, and the moving device inserts a plurality of connector terminals one by one into the connector housing by moving the second fixture.

18. The connector assembly system of claim 17, wherein the detection circuit is one of a plurality of detection circuits, the first end of each detection circuit is electrically connected to the detection component, and the second end of each detection circuit electrically connects to one of the plurality of connector terminals.
